(19) United States
(12) Patent Application Publication
(10) Pub. No.: US 2025/0224187 A1
(43) Pub. Date: Jul. 10, 2025

(54) SEALING SYSTEM AND METHOD

(71) Applicant: ERWIN QUARDER SYSTEMTECHNIK GMBH, Espelkamp (DE)

(72) Inventors: Alexander HEITBRINK, Stemwede (DE); Georg SIEWERT, Pohlheim (DE)

(73) Assignee: ERWIN QUARDER SYSTEMTECHNIK GMBH, Espelkamp (DE)

(21) Appl. No.: 19/083,251

(22) Filed: Mar. 18, 2025

Related U.S. Application Data
(63) Continuation of application No. PCT/EP2024/054361, filed on Feb. 21, 2024.

(30) Foreign Application Priority Data
Feb. 21, 2023 (DE) 102023104233.5

(51) Int. Cl. F28F 11/00; F16J 15/02

(52) U.S. Cl. CPC F28F 11/00; F16J 15/022

(57) ABSTRACT

A sealing site is arranged between a plastic wall of a first component and a metallic, including aluminum, wall of the second component, wherein the metallic, including aluminum, wall is connected to the plastic wall. An areal sealing part made of a metallic material covers the sealing site while sealing the sealing site in a liquid-tight manner. The areal sealing part is connected to the plastic wall of the first component in a liquid-tight manner and is welded in a liquid-tight manner to the metallic, including aluminum, wall of the second component.

### CROSS-REFERENCE TO RELATED APPLICATIONS

This patent application is a continuation of, and as such claims priority to, International Patent Application No. PCT/EP2024/054361, filed on Feb. 21, 2024, which claims priority to and all advantages of German Patent Application No. DE102023104233.5, filed on Feb. 21, 2023; each of the foregoing applications are incorporated herein by reference in their entireties.

### BACKGROUND

Not only for apparatus such as cooling devices for power electronics components but also in applications where special sealing requirements are to be met, plastic and metal materials may be combined with each other in order to combine the specific advantages of the respective materials.

Depending on the design of the apparatus, the question then often arises as to whether the sealing between these materials is sufficiently liquid-tight.

US 2022/395933 A1 discloses a method for the formation of a hermetic pressure fit between a component and an inner element. The method comprises the steps of the connection of one component to another component by the application of heat to the first component or the second component or to a plurality thereof and the cooling of the first component and the second component, wherein the step of the application of heat and of the cooling forms the hermetic sealing by the application of pressure of a hermetic element to the second component and to the inner element.

US 2022/305597 A1 discloses a method for the manufacturing of a hybrid heat exchanger. The method comprises a laser texturing of a metal surface to create a plurality of micro-structures, and the subsequent fusion bonding of a plastic component to the plurality of micro-structures. During the process of fusion bonding, the plastic component bonds to the metal surface.

US 2008/260455 A1 discloses a composite seal in which a first and a second metal layer are located at a distance above one another. A mineral layer is located between the metal layers. The metal and mineral layers have an inner perimeter and an outer perimeter, wherein the inner perimeters overlap to form an opening. The metal layers are connected at one border, e.g., at the outer border, by welding. The metal layers are e.g., films made of precious metal or high temperature alloys, and the mineral layer may be mica, vermiculite or modifications of vermiculite.

### SUMMARY

The present disclosure relates to a sealing system for the liquid-tight sealing of a sealing site which is arranged between a plastic wall of a first component and a wall made of a metallic material, such as aluminum, wherein the wall made of a metallic material is, e.g., connected to this plastic wall, such as in a substance-to-substance bonded manner and/or in a form-fit manner. In addition, the disclosure relates to a method for the sealing of such a sealing site and to an apparatus comprising such first and second components and such a sealing site.

A sealing system in accordance with the disclosure with a sealing part, with a first component and with a second component, is thus characterized by a separate, areal, sealing part made of a metallic material, e.g., of aluminum, which covers the sealing site while sealing the same in a liquid-tight manner, wherein, on the one hand, it is connected to the plastic wall of the first component in a liquid-tight manner, in a substance-to-substance bonded manner, and, on the other hand, is welded, e.g., by laser welding, in a liquid-tight manner to the wall made of the metallic material of the second component.

A “metallic” material is understood to be a material in which at least one component is made of metal. This can therefore be pure metals, but also alloys such as steel.

The use in accordance with the disclosure of a separate sealing part made of such a metallic material allows in accordance with the disclosure to seal the respective sealing site in an especially reliable liquid-tight manner, wherein the sealing part is then on the one hand connected to the plastic wall in a liquid-tight manner and on the other hand is welded to the wall made of the metallic material in a liquid-tight manner, by using suitable connection methods.

In accordance with the disclosure, the sealing part can advantageously have a thickness, at least in a deformation section, which allows for an elastic deformation of the same which is able to compensate for material-related and/or design-related differences in the thermal expansion behaviour of the plastic wall of the first component and the wall made of the metallic material of the second component.

If the sealing site is a, e.g., circumferential, sealing gap between the plastic wall of the first component and the wall made of the metallic material of the second component, the sealing part can be a, e.g., circumferential, sealing frame which covers the sealing gap while sealing the sealing gap in such a way that a first, circumferential, connection section of the sealing part is connected to the first component in a liquid-tight manner, and a second, circumferential, connection section of the sealing part to the second component.

It is possible that the two connection sections of the sealing frame extend in different planes and are connected to one another by an intermediate section which connects them to one another by the deformation section.

As far as the liquid-tight connection between the sealing part on the one hand and the plastic wall of the first component on the other hand is concerned, it is possible that this comprises that at least one connection surface of the plastic wall of the first component is pressed with a connection surface of the sealing part made of the metallic material, with a connection surface which is arranged at the first connection section, wherein the connection surface of the sealing part has a nano- and/or micro-structuring which is applied, by a chemical and/or physical micro-structuring method, into the connection surface, wherein the nano- and/or micro-structuring causes a surface enlargement and/or has three-dimensional recesses, which e.g., comprise undercuts, and/or has barbs.

As far as the liquid-tight connection between the sealing part on the one hand and the wall made of the metallic material of the second component on the other hand is concerned, it is possible that this comprises that at least one connection surface of the sealing part is connected to a connection surface of the wall made of the metallic material of the second component by laser beam welding, by through-transmission laser welding.

The method in accordance with the disclosure of for the liquid-tight sealing between the plastic wall of the first component and the wall made of the metallic material of the second component comprises at least the following measures:
a) processing of a or, respectively, the first connection surface of a or, respectively, the sealing part by a chemical and/or physical micro-structuring method so that nano- and/or micro-structures are being applied into this connection surface, wherein the nano- and/or micro-structures cause a surface enlargement and/or have recesses which comprise undercuts and/or have barbs,
b) covering of the sealing site with the sealing part in a liquid-tight manner, wherein
b1) the first connection surface of the sealing part is being pressed in a liquid-tight manner with the connection surface of the plastic wall of the first component, and wherein
b2) the second connection surface of the sealing part is being welded in a liquid-tight manner to the connection surface of the wall made of the metallic material of the second component, by a laser.

As far as the apparatus in accordance with the disclosure of is concerned, it is possible that this is a hybrid cooling component for the dissipation of heat from objects to be cooled, such as from power electronics modules, wherein a cooling medium which is able to dissipate the waste heat can be conducted through the hybrid cooling component, wherein the first component with the plastic wall is a basic body made of plastic of the hybrid cooling component and wherein the second component with the wall made of the metallic material is a cooling body made of a metallic material of the hybrid cooling component, wherein objects to be cooled can be arranged on the cooling body and wherein the cooling body is connected, in a substance-to-substance bonded manner and/or in a form-fit manner, to the basic body made of plastic, while forming the sealing site which is covered by the sealing part and forms a circumferential gap.

In this context, the sealing part can be a, circumferential, e.g., closed sealing frame, which covers the sealing gap. This in such a way that a first, circumferential, in preference closed, connection surface of the sealing frame, a connection strip, is connected in a liquid-tight manner to a, circumferential, connection surface, a connection strip, of the plastic wall of the basic body of the hybrid cooling component, and a second, e.g., circumferential, in preference closed, connection surface of the sealing frame, a connection strip, to a, circumferential, connection surface of the cooling body of the hybrid cooling component.

Advantageously, the liquid-tight connection between the sealing frame on the one hand and the plastic wall of the basic body on the other hand can comprise that the connection surface of the plastic wall of the basic body is pressed with the first connection surface of the sealing frame, wherein the first connection surface of the sealing frame has a nano- and/or micro-structuring which is applied, by a chemical and/or physical micro-structuring method, into the connection surface, wherein the nano- and/or micro-structuring causes a surface enlargement and/or has recesses which comprise undercuts and/or has barbs.

At least one object to be cooled can be arranged in the hybrid cooling component and can be connected to the cooling body while bearing against the latter. An outer side of the object to be cooled, made of a metallic material, can be welded to one side of the cooling body.

As for the rest, one side of the cooling body can form a limitation surface of a cooling medium channel of the hybrid cooling component, through which a cooling medium can be conducted for the evacuation of waste heat of an object to be cooled or of the object to be cooled. On the other hand, another side of the cooling body can form a or, respectively, the cooling surface on which an object to be cooled or the object to be cooled can be arranged or is arranged, by welding of the outer side of the object to be cooled to this other side of the cooling body.

In addition, it is possible that the sealing frame comprises a first, e.g., outer, border section, on which the first connection surface is arranged, and comprises a second, e.g., inner, border section, on which the second connection surface is arranged, and in that between these two border sections there is arranged a deformation section of the sealing frame which has a thickness which allows for an elastic deformation of the same which is able to compensate for material-related and/or design-related differences in the thermal expansion behaviour of the plastic wall of the basic body and the metallic material of the cooling body.

### BRIEF DESCRIPTION OF THE DRAWINGS

Further features of the present disclosure are apparent from the appended claims, from the following description of an exemplary embodiment of the disclosure, and from the appended drawings. In the drawings:

FIG. 1 shows a hybrid cooling component in an oblique view (partially cut), in which a sealing site is sealed with a sealing system;

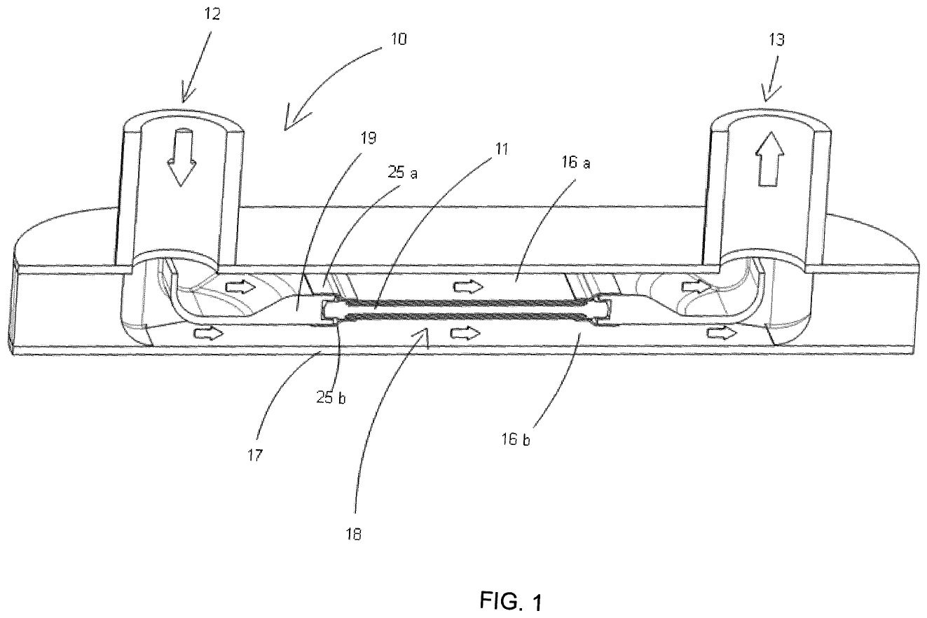

FIG. 2 shows the hybrid cooling component of FIG. 1, as well in an oblique view (partially cut), in which details have been omitted;

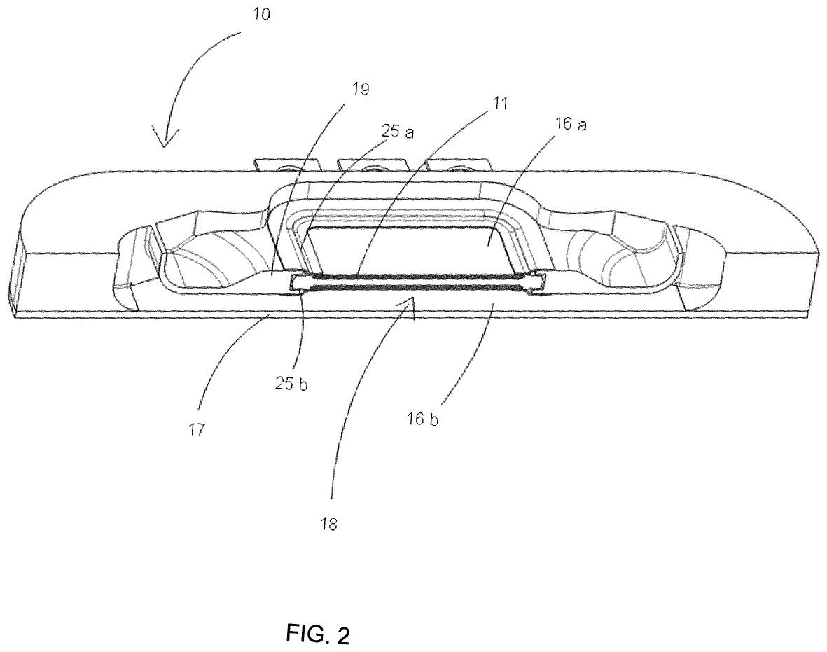

FIG. 3 shows the hybrid cooling component from FIG. 1 in a longitudinal section;

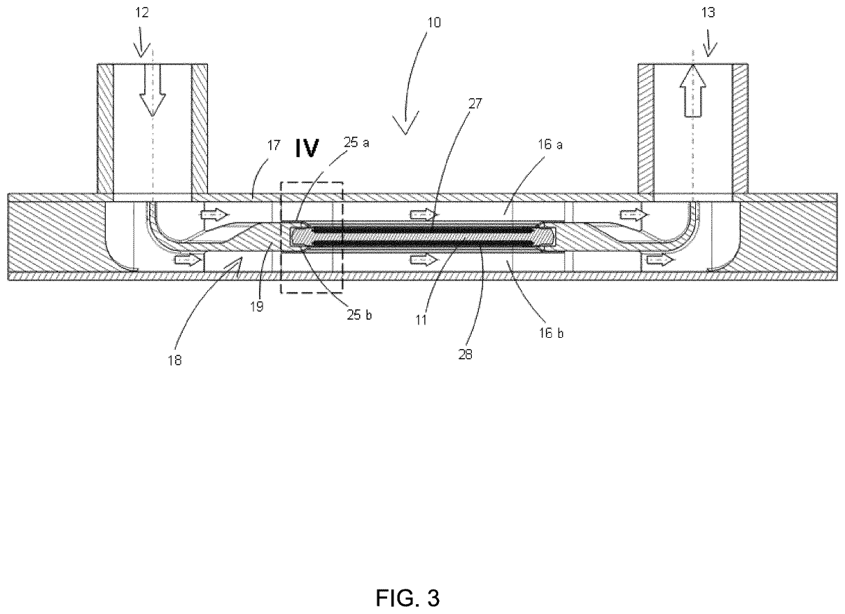

FIG. 4 shows the detail IV in FIG. 3 in an enlarged view.

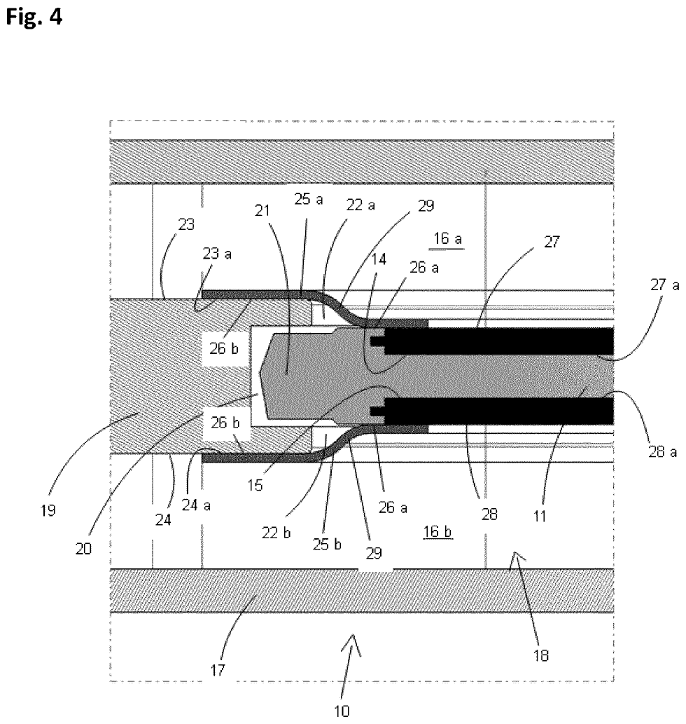

### DETAILED DESCRIPTION

The sealing system in accordance with the disclosure is herein explained with reference to a hybrid cooling component 10, by which heat is dissipated from objects to be cooled, in that a cooling medium, such as a cooling liquid, which originates from a cooling liquid source (not shown), is conducted through the hybrid cooling component 10 and waste heat, which is emitted by an object 11 to be cooled, is transported away by the cooling medium. However, the sealing system can also be used in conjunction with some other apparatus.

In the present example, the hybrid cooling component 10 comprises an inlet 12, via which the cooling medium is fed into the hybrid cooling component 10, and an outlet 13, via which the cooling medium is fed out of the hybrid cooling component 10 again after having received the heat from the object 11 to be cooled. The object 11 to be cooled can be a power electronics chip, for example.

In the present example, both the top surface 14 and the bottom surface 15 of the object 11 to be cooled are to be cooled. For this reason, the cooling medium is guided along both the top surface 14 and the bottom surface 15, in each case through a cooling channel 16a or, respectively, 16b of the hybrid cooling component 10.

In the present example, the hybrid cooling component 10 comprises an injection-moulded basic body 17 made of plastic, which has various walls and an internal space 18 in which the cooling channels 16a and 16b are formed and the object 11 to be cooled is arranged.

In addition, the hybrid cooling component 10 comprises cooling bodies 27 and 28, each made or consisting of a metallic material, aluminum, which are arranged in parallel planes and between which the object 11 to be cooled is located, wherein the (upper) cooling body 27 rests against the top surface 14 of the object 11 to be cooled and the (lower) cooling body 28 rests against the bottom surface 15 of the object 11 to be cooled. The top surface 14 and the bottom surface 15 of the object 11 to be cooled can, for example, each be welded to the cooling body 27 or 28.

An inner wall 19 of the basic body 17 which is arranged in the internal space 18 comprises a frame-like, circumferential edge area with a circumferential connection groove 20, in which the (circumferential) border section 21 of the object 17 to be cooled is arranged. In the present example, the border section 21 is connected to the inner wall 19 in a substance-to-substance bonded manner.

Between the object 11 to be cooled and the inner wall 19 of the basic body 10 there are sealing sites which are each formed as circumferential sealing gaps 22a and 22b and through which in the absence of sealing the cooling medium which is flowing through the cooling channels 16a and 16b could or would inadvertently penetrate between the object 11 to be cooled and the inner wall 19.

In this example, the one sealing gap 22a is arranged between the top surface 14 of the object 11 to be cooled and the top surface 23 of the inner wall 19 of the basic body 17, the other sealing gap 22b is arranged between the bottom surface 15 of the object 11 to be cooled and the bottom surface 24 of the inner wall 19 of the basic body 17.

Now, for the liquid-tight sealing of the sealing gaps 22a and 22b, a sealing system is provided in each case, which in the present example comprises an areal, frame-like sealing part or, respectively, a sealing frame 25a for the sealing of the sealing gap 22a and a sealing frame 25b for the sealing of the sealing gap 22b. It will be understood that, depending on the application or depending on the type of the sealing site, other sealing parts can also be used which are not of a frame-like design.

The sealing parts or, respectively, sealing frames 25a, 25b are each manufactured from a metallic material, preferably aluminum, or consist of this material. For the liquid-tight sealing, they cover the respective sealing gap 22a or 22b, respectively, and are each connected to the inner wall 19 of the basic body 17 and as well with the respective cooling body 27 or, respectively, 28 in a liquid-tight manner.

An inner, circumferential border and connection area of each sealing frame 25a, 25b has, in the present example, a respective, strip-shaped connection surface 26 a, which is connected in a liquid-tight manner by a correspondingly oppositely located, circumferential, strip-shaped connection surface 27a or, respectively, 28a to the outer side of the respective cooling body 27 or, respectively, 28.

An outer, circumferential border and connection area of each sealing frame 25a, 25b has a respective strip-shaped connection surface 26 b, which is connected in a liquid-tight manner by a correspondingly oppositely located, circumferential, strip-shaped connection surface 23a or, respectively, 24 to the top surface 23 of the (plastic) inner wall 19 or, respectively, to the bottom surface 24 of the inner wall 19.

For this fluid-tight connection of the top surface 23 of the (plastic) inner wall 19 with the outer (metallic) connection surface 26 b of the sealing frame 25a or, respectively, for the connection of the bottom surface 24 of the inner wall 19 to the outer connection surface 26 b of the sealing frame 25b, the respective outer connection surface 26 b of the respective sealing frame 25a, 25b has a nano- and/or micro-structuring which is applied, by a chemical and/or physical micro-structuring method, into the outer connection surface 26 b, and has a nano- and/or micro-structuring which causes a surface enlargement and/or has recesses which comprise undercuts and/or has barbs.

This connection surface 26 b which has been processed in this way is then in each case pressed with the (plastic) inner wall 19 in the course of the manufacturing of the hybrid cooling component 10. However, it has to be understood that it is in theory also conceivable to use other connection techniques to produce this fluid-tight connection.

The fluid-tight connection between the respective inner (metallic) connection surface 26 a on the one hand and the respective oppositely located (metallic) connection surface 27a or, respectively, 28a of the upper cooling body 27 or, respectively, of the lower cooling body 28 on the other hand is being achieved in the present example by laser (seal) welding of these two metallic surfaces. In this case too, it will be understood that other connection methods are also possible in order to produce this fluid-tight connection.

In addition, each sealing frame 20, 25b has a deformation section 29 formed as an intermediate section, which is arranged between the outer and the inner border or connection section of the respective sealing frame 25a or 25b and which has a thickness, in the present example of a few mm, which allows for an elastic deformation of the deformation section 29, so that material-related and/or design-related differences in the thermal expansion behaviour of the (plastic) inner wall 19 of the basic body 17 and the metallic material of the cooling body 27 or, respectively, 28 can be compensated.

### LIST OF REFERENCE NUMBERS

10 hybrid cooling component
11 object to be cooled
12 inlet
13 outlet
14 top surface of the object to be cooled
15 bottom surface of the object to be cooled
16a cooling channel
16b cooling channel
17 basic body of the hybrid coiling component
18 internal space
19 inner wall
20 connection groove of the inner wall
21 border section of the object to be cooled
22a sealing gap
22b sealing gap
23 top surface of the inner wall
23a connection surface of the top surface
24 bottom surface of the inner wall
24a connection surface of the bottom surface
25a sealing frame
25b sealing frame
26a inner connection surface of the sealing frame
26b outer connection surface of the sealing frame
27 upper cooling body
27a connection surface of the upper cooling body
28 lower cooling body
28a connection surface of the lower cooling body
29 deformation section

What is claimed is:

1. A sealing system for the liquid-tight sealing of a sealing site which is arranged between a plastic wall of a first component and a metallic, including aluminum, wall of the second component, wherein the metallic, including aluminum, wall is connected to the plastic wall, the sealing system comprising:
an areal sealing part made of a metallic material which covers the sealing site while sealing the sealing site in a liquid-tight manner, wherein, the areal sealing part is connected to the plastic wall of the first component in a liquid-tight manner and is welded in a liquid-tight manner to the metallic, including aluminum, wall of the second component.

2. The sealing system of claim 1, wherein the areal sealing part has a thickness, at least in a deformation section, which allows for an elastic deformation of the areal sealing part arranged to compensate for material-related and/or design-related differences in the thermal expansion behaviour of the plastic wall of the first component and the metallic, including aluminum, wall of the second component.

3. The sealing system of claim 1, wherein
the sealing site is a circumferential sealing gap between the plastic wall of the first component and the metallic, including aluminum, wall of the second component,
the sealing part is a circumferential sealing frame which covers the sealing gap while sealing the sealing gap such that a first circumferential connection section of the sealing part is connected to the first component in a liquid-tight manner, and
a second circumferential connection section of the sealing part is connected to the second component in a liquid-tight manner.

4. The sealing system of claim 3, wherein the two connection sections of the sealing frame extend in different planes and are connected to one another by an intermediate section which connects them to one another by the deformation section.

5. The sealing system of claim 1, wherein
the liquid-tight connection between the sealing part and the plastic wall of the first component comprises that at least one connection surface of the plastic wall of the first component is pressed with a connection surface of the sealing part made of the metallic material,
the connection surface of the sealing part made of the metallic material is arranged at the first connection section,
the connection surface of the sealing part has a nano- and/or micro-structuring which is applied by a chemical and/or physical micro-structuring method into the connection surface, and
the nano- and/or micro-structuring causes a surface enlargement and/or has three-dimensional recesses, which comprise undercuts, and/or has barbs.

6. The sealing system of claim 3, wherein the liquid-tight connection between the sealing part and the metallic, including aluminum, wall of the second component comprises that at least one connection surface of the sealing part is connected to a connection surface of the metallic, including aluminum, wall of the second component by through-transmission laser beam welding, wherein the connection surface of the sealing part is arranged at the second connection section.

7. A method for sealing a sealing site between a plastic wall of a first component and an metallic, including aluminum, wall of a second component, by a sealing system of claim 1, wherein the metallic, including aluminum, wall is connected to the plastic wall, in a substance-to-substance bonded manner and/or in a form-fit manner, the method comprising:
a) processing a first connection surface of an areal sealing part made of a metallic material by a chemical and/or physical micro-structuring method, so that nano- and/or micro-structures are applied to the first connection surface, wherein the nano- and/or micro-structures cause a surface enlargement and/or have recesses which comprise undercuts and/or have barbs,
b) covering the sealing site with the sealing part in a liquid-tight manner, wherein
b1) a first connection surface of the sealing part is pressed in a liquid-tight manner with a connection surface of the plastic wall of the first component, and
b2) a second connection surface of the sealing part is welded in a liquid-tight manner to a connection surface of the wall made of the metallic material of the second component.

8. An apparatus, comprising:
a first component with a plastic wall; and
a second component with a wall made of a metallic material;
wherein the wall made of a metallic material is connected to the plastic wall of the first component;
wherein a sealing site is located between the plastic wall of the first component and the wall made of the metallic material of the second component;
wherein the sealing site is sealed in a liquid-tight manner by a sealing system which includes a sealing part made of a metallic material which covers the sealing site while sealing the sealing site in a liquid-tight manner; and
wherein the sealing part is connected to the plastic wall of the first component in a liquid-tight manner and the sealing part is welded in a liquid-tight manner to the wall made of the metallic material of the second component.

9. The apparatus of claim 8, wherein
the apparatus is a hybrid cooling component for the dissipation of heat from objects to be cooled;
a cooling medium for dissipating the waste heat is conductable through the hybrid cooling component;
the first component with the plastic wall includes a basic body made of plastic of the hybrid cooling component and the second component with the wall made of the metallic material includes a cooling body made of a metallic material of the hybrid cooling component;
objects to be cooled can be arranged on the cooling body; and
the cooling body is connected to the basic body made of plastic while forming the sealing site which is covered by the sealing part and forms a circumferential gap.

10. The apparatus of claim 9, wherein the sealing part is a sealing frame which covers the sealing gap such that a first connection surface of the sealing frame is connected in a liquid-tight manner to a connection surface of the plastic wall of the basic body of the hybrid cooling component, and a second connection surface of the sealing frame is connected in a liquid-tight manner to a circumferential connection surface of the cooling body of the hybrid cooling component.

11. The apparatus of claim 10, wherein
the liquid-tight connection between the sealing frame and the plastic wall of the basic body comprises that the connection surface of the plastic wall of the basic body is pressed with the first connection surface of the sealing frame;
the first connection surface of the sealing frame has a nano- and/or micro-structuring which is applied by a chemical and/or physical micro-structuring method into the connection surface; and
the nano- and/or micro-structuring causes a surface enlargement and/or has recesses which comprise undercuts and/or has barbs.

12. The apparatus of claim 9, wherein an object to be cooled is arranged in the hybrid cooling component and is connected to the cooling body while bearing against the cooling body.

13. The apparatus of claim 9, wherein one side of the cooling body forms a limitation surface of a cooling medium channel of the hybrid cooling component, through which a cooling medium is conductable for the evacuation of waste heat of the object to be cooled, and another side of the cooling body forms a cooling surface for the object to be cooled.

14. The apparatus of claim 9, wherein
the sealing frame comprises a first, outer, border section, on which the first connection surface is arranged, and a second, inner, border section, on which the second connection surface is arranged;
between the two border sections there is arranged a deformation section of the sealing frame which has a thickness which allows for an elastic deformation of the deformation section which is able to compensate for, material-related and/or design-related differences in the thermal expansion behaviour of the plastic wall of the basic body and the metallic material of the cooling body.
